(19) United States
(12) Patent Application Publication
(10) Pub. No.: US 2020/0144074 A1
(43) Pub. Date: May 7, 2020

(54) PROCESS FOR THE ETCHING METAL- OR SEMIMETAL-CONTAINING MATERIALS

(71) Applicant: BASF SE, Ludwigshafen am Rhein (DE)

(72) Inventors: Torben ADERMANN, Ludwigshafen (DE); Falko ABELS, Ludwigshafen (DE); Stephan ZUEND, Fremont, CA (US); Hagen WILMER, Ludwigshafen (DE)

(73) Assignee: BASF SE, Ludwigshafen am Rhein (DE)

(21) Appl. No.: 16/495,180

(22) PCT Filed: Apr. 9, 2018
(86) PCT No.: PCT/EP2018/058961

§ 371 Date: Sep. 18, 2019

(30) Foreign Application Priority Data
Apr. 13, 2017 (EP) 17166419.6

(51) Int. Cl. H01L 21/3213; C23F 1/12; C23F 1/02; C09K 13/00

(52) U.S. Cl. CPC H01L 21/32135; C09K 13/00; C23F 1/02; C23F 1/12

(57) ABSTRACT

The present invention is in the field of etching metal- or semimetal-containing materials by atomic layer etching. In particular the present invention relates to a process for etching a metal- or semimetal-containing material comprising bringing a metal- or semimetal-containing material having an activated surface in contact with an organic compound containing a leaving group which is capable of forming a volatile compound upon coming in contact with the metal- or semi-metal-containing material and a group which is capable of coordinating to a metal or semimetal atom in the metal- or semimetal-containing material.

The present invention is in the field of etching metal- or semimetal-containing materials by atomic layer etching.

With the ongoing miniaturization, e.g. in the semiconductor industry, the need for metal- or sem-imetal-containing materials with fine structures increases while the requirements of the quality of such materials become stricter. Thin metal- or semimetal-containing materials serve different purposes such as dielectrics, conducting features, capping, or separation of fine structures. Classical etching processes are wet chemical processes. These processes have the drawback that very fine structures can often not be reached. Also, process control, e.g. with regard to the thickness of material which is removed, is limited. Vapor-based technologies, in particular atomic layer etching, overcome these limitations.

US 2015/0 270 140 discloses a process for etching a metal- or semimetal-containing material including bringing it in contact with a volatile organic compound, e.g. ethanol. However, this etching process is not efficient enough for many applications.

U.S. Pat. No. 9,130,158 discloses a process for etching a metal- or semimetal-containing material including bringing it in contact with an organic solvent vapor, such as alcohols, and an organic ligand solvent. However, this etching process is also not efficient enough for many applications.

It was an object of the present invention to provide a process for etching metal- or semimetal-containing materials which removes the metal more efficiently, leaving less impurity traces. The process was aimed to be fast and applicable to a broad variety of different metals.

These objects were achieved by a process for etching a metal- or semimetal-containing material comprising bringing a metal- or semimetal-containing material having an activated surface in contact with an organic compound containing a leaving group which is capable of forming a volatile compound upon coming in contact with the metal- or semimetal-containing material and a group which is capable of coordinating to a metal or semimetal atom in the metal- or semimetal-containing material.

The present invention further relates to the use of an organic compound containing a leaving group which is capable of forming a volatile compound upon coming in contact with a metal- or semimetal-containing material and a group which is capable of coordinating to a metal or semimetal atom in the metal- or semimetal-containing material for an etching process.

Preferred embodiments of the present invention can be found in the description and the claims. Combinations of different embodiments fall within the scope of the present invention.

The metal- or semimetal-containing material can contain any metal or semimetal including Mg, Al, Si, Ti, V, Cr, Mn, Fe, Co, Ni, Cu, Zn, Ga, Ge, As, Y, Zr, Nb, Mo, Ru, Rh, Pd, Ag, Cd, In, Sn, Sb, Pr, Nd, Pm, Sm, Eu, Gd, Tb, Dy, Ho, Er, Tm, Yb, Lu, Hf, Ta, W, Re, Os Ir, Pt, Au. Transition metals or silicon are preferred, in particular Co, Fe, Pd, Pt, Mn, Mg, Ru, Ta, Al, Cr, Zr, or W. Preferably, the metal- or semimetal-containing material contains at least 50 at-% metal and/or semimetal, more preferably at least 70 at-%, even more preferably at least 90 at-%, in particular at least 99 at-%. “At-%” means as typical in the field that all metals and/or semimetal atoms con-tained in the material together represent the given percentage of total atoms in the material.

According to the present invention, the metal- or semimetal-containing material has an activated surface. Activated surface means that the surface is chemically or physically modified such that surface reaction rates are significantly different in comparison to a surface which is not activated. Activation can be achieved in various ways, for example by halogenation of the surface, by oxidation of the surface, or by introducing surface lattice defects. Oxidation can for example be achieved with a vapor of H₂O₂, HClO, O₂, O₃, SOCl₂, NH₄OH, HCHO, COS or CH₃OH. A plasma can increase the efficiency of oxidation. Surface lattice defects can for example be achieved by radiation, ultrasound, or very short heating.

Preferably, the activated surface of the metal- or semimetal-containing material contains a halo-gen. Halogens include fluorine, chlorine, bromine, and iodine, preferably fluorine or chlorine, in particular fluorine. Preferably, the halogen concentration in the metal- or semimetal-containing material in a layer extending 0.5 nm from the surface is significantly higher compared to the bulk material, preferably 10 times higher, in particular 100 times higher. Ideally, only the surface atomic monolayer contains halogens, but not the rest. However, in practice it is only possible to come close to this ideal situation.

Introducing halogens at the surface of the metal- or semimetal-containing material can be achieved in various ways. The metal- or semimetal-containing material can be exposed to halo-gen-containing compounds including F-containing compounds such as F₂, HF, CH₃F, CH₂F₂, CHF₃, CF₄, C₄F₈, COF₂, NF₃, PF₃, SF₆, FCl, ClF₃; Cl-containing compounds such as Cl₂, HCl, CH₃Cl, CH₂Cl₂, CHCl₃, CCl₄, C₂H₃Cl, C₂H₂Cl₂, BCl₃, CF₃Cl, SiH₃Cl, SiH₂Cl₂, SiHCl₃, SiCl₄, POCl₃, SOCl₂, SO₂Cl₂; Br-containing compounds such as Br₂, HBr, BBr₃, CF₃Br; or I-containing compounds such as I₂, HI, CF₃I. Preferably, the halogen-containing compound is in the vapor phase when coming in contact with the surface of the metal- or semimetal-containing material. The halogen-containing compound can be mixed with an inert gas, for example He, Ne, or Ar. Typically, a halogenation reaction occurs producing partially or fully halogenated metal and/or semimetal atoms. The reaction usually takes between 100 ms and 1 min, preferably 500 ms to 30 s, for example 1 to 10 s. The pressure of the vapor phase during the halogenation reaction is typically 1 to 100 mbar, preferably 2 to 50 mbar, such as 5 to 20 mbar.

The halogenation reaction rate on the surface can be increased by increasing of the temperature, such as to 50° C. or to 300° C., preferably 100° C. to 200° C. Alternatively or additionally, the halogen-containing compound can be converted into a plasma before or while coming in contact with the metal- or semimetal-containing material. A plasma is typically generated by applying a high frequency RF field, for example a frequency of 13.56 MHz. Typical power input is 200 to 2000 W, preferably 500 to 1000 W.

Preferably, after completion of the halogenation reaction, any residual vapor is removed by purging with an inert gas, for example nitrogen, helium, or argon. Alternatively, the residual vapor can be removed by high vacuum, such as lowering the pressure to 0.1 to 10⁻⁶ mbar.

The metal- or semimetal-containing material having an activated surface is brought in contact with an organic compound containing a leaving group which is capable of forming a volatile compound when being brought in contact with the activated surface of the metal- or semimetal-containing material. This leaving group preferably contains B, Al, Si, Ge or Sn as these ele-ments readily form volatile compounds.

The organic compound further contains a group which is capable of coordinating to a metal or semimetal atom in the metal- or semimetal-containing material. Preferably, such a coordinating group contains nitrogen. Examples include aliphatic amines like dialkylamine, piperidine, pyrroli-dine, morpholine; or aromatic amines like pyrrole, indole, pyridine, or pyrazine; amides like for-maide or acetamide; imides in particular cyclic imides like succinic imide, maleic imide or phthalic imide. More preferably the coordinating group contains at least two nitrogen atoms. Examples include amidinates such as acetamidine or N,N′-bis-iso-propylacetamidine; guanidinates such as guanidine; aminoimines such as 2-N-tert-butylamino-2-methylpropanal-N-tertbuylimine; diimines such as glyoxal-N,N′-bis-isopropyl-diimine, glyoxal-N,N′-bis-tert-butyl-diimine or 2,4-pentanedione-diimine; diketiminates such as N,N′-2,4-pentanediketiminate; iminopyrroles including pyrrol-2-carbald-alkylimines such as pyrrol-2-carbald-ethylimine, pyrrol-2-carbald-isopropylimine or pyrrol-2-carbald-tert-butylimine as well as pyrrol-2,5-biscarbald-alkyldiimines such as pyrrol-2,5-biscarbald-tert-butyldiimine.

The coordinating group can also contain phosphor. These include phosphane or trisubstituted phosphanes including trihalogenphosphanes, trialkylphosphanes, dialkylarylphosphanes, alkyl-diarylphosphanes or triarylphosphanes, wherein the alkyl or the aryl groups can be the same or different to each other if more than one alkyl or aryl group is present. Examples include trifluoro phosphane, trimethyl phosphane, trimethoxyphosphane, methyl-dimethoxy phosphane, tri-tertbutyl phosphane, tricyclohexyl phosphane, di-isopropyl-tert-butyl phosphane, dimethyl-tert-butyl phosphane, triphenyl phosphane, and tritolylphosphane. It is also possible that the coordinating group contains two or more phosphor atoms. Such compounds include diphos-phinoethanes such as 1,2-bis(diethylphosphino)ethane.

The coordinating group can also contain an unsaturated hydrocarbon. These can be aliphatic or aromatic, preferably aliphatic. Unsaturated hydrocarbons include olefins like ethylene, propyl-ene, iso-butylene, cyclohexene, cyclohexadiene, cyclooctene, cyclooctadiene, cyclooctadiene, styrene; and alkynes like ethyne, propyne, 2-butyne. Aromatic hydrocarbons include cyclopen-tadiene and its derivatives; benzene and its derivatives such as toluene or xylene.

The coordinating group can also contain an oxygen atom. Examples are alkanolates such as methanolate, ethanolate and isopropanolate; ethers such as tetrahydrofurane; carboxylates such as formiate, acetate, propionate, butanolate; acetylacetonate and its derivatives such as 1,5-di-tert-butyl-acetylacetonate or 1,1,1,5,5,5-pentafluoroacetylacetone. Further, the coordinating group can contain both an oxygen and a nitrogen atom. Examples including dimethylamino-isopropanol, formamide, acetamide, 2,4-pentandione-N-alkylimines such as 2,4-pentandione-N-isopropylimine.

Preferably, the leaving group in the organic compound is bond to an atom which acts as coordination site after cleavage of the leaving group. Often, cleavage of the leaving group by reaction with a halogen causes this coordinating site to be anionic.

Preferably the coordinating group contains nitrogen and this nitrogen is bond to a silicon atom of the leaving group. Some preferred examples are shown below.

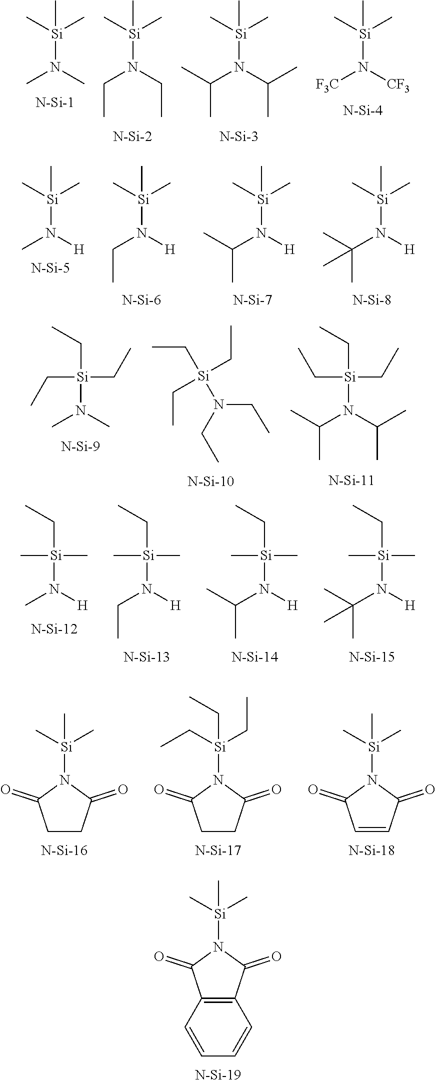

Also preferably, the coordinating group contains oxygen and this oxygen is bond to a silicon atom of the leaving group, in particular the coordingating group is a alkanolate or a carboxylate in which an alkanolate or carboxylate oxygen is bond to a silicon atom of the leaving group. Some preferred examples are shown below.

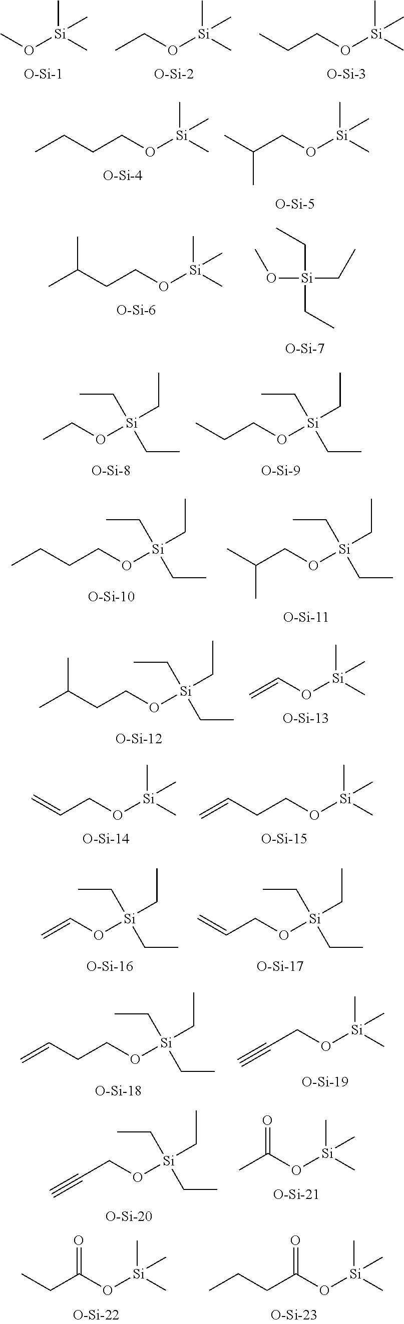

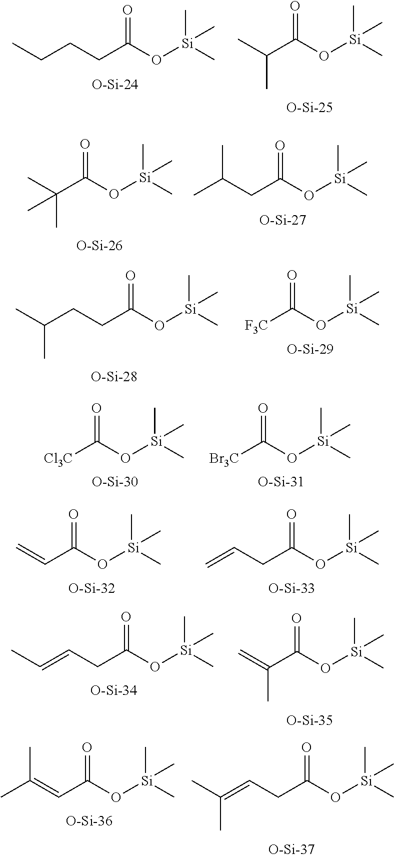

Also preferably, the coordinating group is an olefinic diamine, in which at least one nitrogen atom is attached to a a silicon atom of the leaving group. These include compounds of general formula (Ia), (Ib), and (Ic).

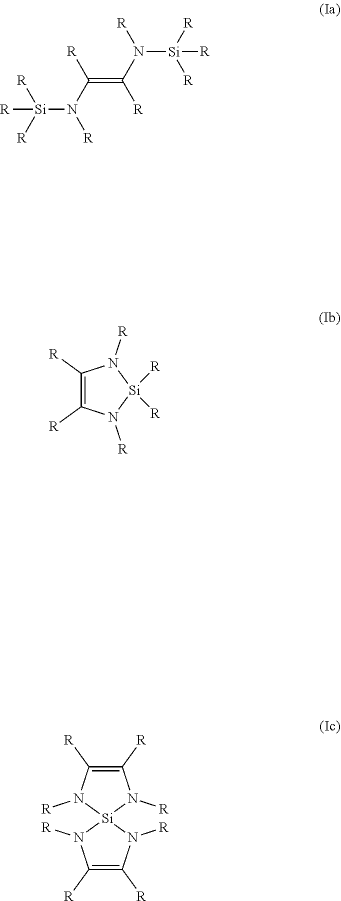

R stands for any conceivable residue, preferably hydrogen, alkyl or fluorinated alkyl, in particular hydrogen, methyl, ethyl, n-propyl, iso-propyl, n-butyl, sec-butyl, iso-butyl, tert-butyl, trifluoro-methyl. Different R can be the same or different to each other.

Preferred examples of compounds of general formula (Ia), (Ib) and (Ic) are given below.

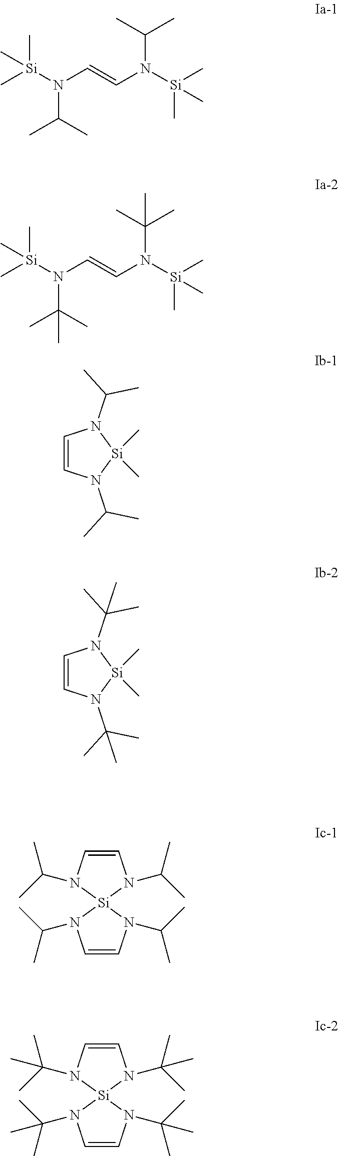

Also preferably, the organic compound contains two coordinating groups containing each two nitrogen atoms and the leaving group is a Si, Ge or Sn atom. These include compounds of general formula (IIa) and (IIb).

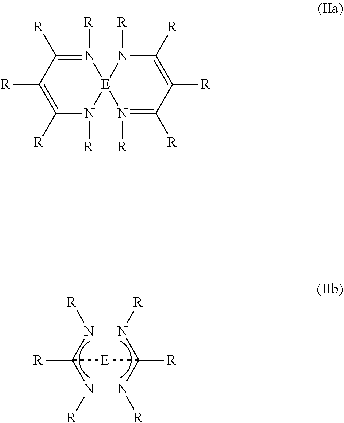

R has the same definition and preferred embodiments as described above. E stands for Si, Ge or Sn.

Preferred examples of compounds of general formula (IIa) and (IIb) are given below.

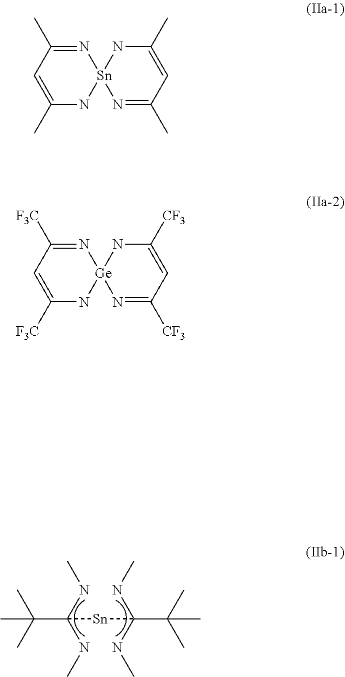

Also preferably, the organic compound contains a cycopentadiene derivative and a boron group. These include compounds of general formula (IIIa) or (IIIb).

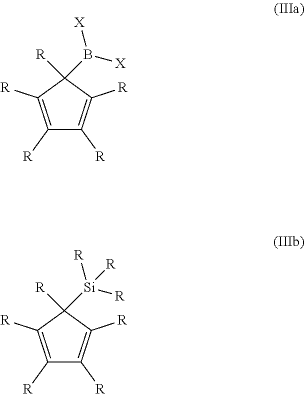

R has the same definition and preferred embodiments as described above. G stands for B or Si. X stands for halogens like F, Cl, Br, or I, preferably Cl or Br. The two X can be the same or different to each other, preferably they are the same. It is also possible, that one or more than one R in the compound of general formula (III) are replaced by a silyl group, in particular by a trime-thylsilyl group.

Preferred examples of compounds of general formula (IIIa) and (IIIb) are given below.

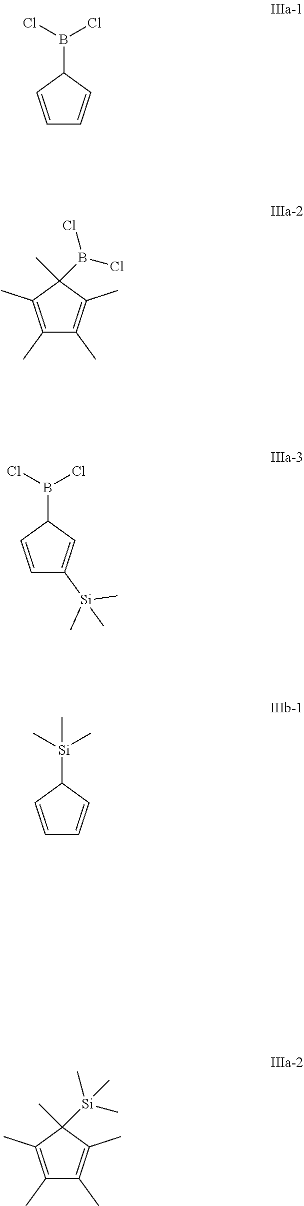

Preferably the molecular weight of the organic compound containing a coordinating group and a leaving group is not more than 1000 g/mol, more preferred not more than 800 g/mol, in particular not more than 600 g/mol.

The organic compound is used in the process according to the present invention is preferably used at high purity to achieve the best results. High purity means that the substance employed contains at least 90 wt.-% of the organic compound, preferably at least 95 wt.-%, more preferably at least 98 wt.-%, in particular at least 99 wt.-%. The purity can be determined by elemental analysis according to DIN 51721 (Prüfung fester Brennstoffe-Bestimmung des Gehaltes an Kohlenstoff and Wasserstoff-Verfahren nach Radmacher-Hoverath, August 2001).

Preferably, the organic compound is in the vapor phase when bringing it in contact with the metal- or semimetal-containing material. The pressure of the vapor containing the organic compound is preferably 0.1 to 10 mbar, more preferably 0.2 to 5 mbar, in particular as 0.5 to 2 mbar. The organic compound can be used as pristine compound or it can be mixed with a different compound in the vapor phase, for example with an inert gas such as nitrogen or argon or with a coordinating gas such as CO or NO.

The temperature of the metal- or semimetal-containing material when it is brought in contact with the organic compound preferably is 20 to 300° C., more preferably 50 to 250° C., in particular 80 to 200° C.

Preferably, after the metal- or semimetal-containing material is brought in contact with an organic compound, any residual excess organic compound is removed by purging with an inert gas, for example nitrogen, helium, or argon. Alternatively, the excess organic compound can be removed by high vacuum, such as lowering the pressure to 0.1 to 10⁻⁶ mbar.

In some cases it is preferable to bring the metal- or semimetal-containing material with the activated surface in contact with an organic solvent prior to bringing it in contact with an organic compound containing a leaving group and a coordinating group. Preferably, the solvent is in the vapor phase when being brought in contact with the metal- or semimetal-containing material. Preferably, the pressure of the solvent vapor is 1 to 100 mbar, more preferably 2 to 50 mbar, in particular 5 to 20 mbar. Organic solvents include alcohols like methanol, ethanol or isopropanol; ethers like dimethylether, diethylether or tetrahydrofurane; esters like methyl formiate, ethyl formiate, methyl acetate, ethyl actetate; aldehydes like formaldehyde or acetaldehyde; ketones like acetone or methyl ethyl ketone; acids like formic acid or acetic acid; amines like trimethyl amine, triethylamine, dimethyl-isopropylamine; amides like N,N-dimethylformamide or N,N-di-methylacetamide.

Preferably, after bringing the metal- or semimetal-containing material in contact with an organic solvent, any residual solvent vapor is removed by purging with an inert gas, for example nitrogen, helium, or argon. Alternatively, the residual vapor can be removed by high vacuum, such as lowering the pressure to 0.1 to 10⁻⁶ mbar.

Preferably, a sequence including activating the surface of the metal- or semimetal-containing material and then bringing it in contact with an organic compound containing a leaving group and a coordinating group is performed at least twice, more preferably at least five times, in particular at least 10 times.

A process containing multiple of said sequence is often referred to as atomic layer etching (ALE). ALE can be employed in the semiconductor manufacturing process, in particular when sub-10 nm technologies are involved. ALE is often combined with passivating layers, such as photocured resins which are irradiated through shadow masks, in order to selectively etch metals or semimetals only in particular areas for building up complex structures.

1. A process for etching a metal- or semimetal-comprising material, the process comprising contacting
a metal- or semimetal-comprising material comprising an activated surface with
an organic compound comprising
a leaving group which is capable of forming a volatile compound contacting the metal- or semimetal-comprising material and
a group which is capable of coordinating to a metal or semimetal atom in the metal- or semimetal-comprising material.

2. The process of claim 1, wherein the activated surface of the metal- or semimetal-comprising material comprises a halogen.

3. The process of claim 1, wherein the leaving group comprises B, Al, Si, Ge or Sn.

4. The process of claim 1, wherein the group which is capable of coordinating to the metal or semimetal atom comprises nitrogen, oxygen, phosphor or an unsaturated hydrocarbon.

5. The process of claim 1, wherein the leaving group is bonded to an atom which acts as a coordination site after cleavage of the leaving group.

6. The process of claim 1, wherein the group which is capable of coordinating to the metal or semimetal atom comprises nitrogen which is bonded to a silicon atom of the leaving group.

7. The process of claim 6, wherein the organic compound is a compound of general formula (Ia), (Ib) or (Ic): 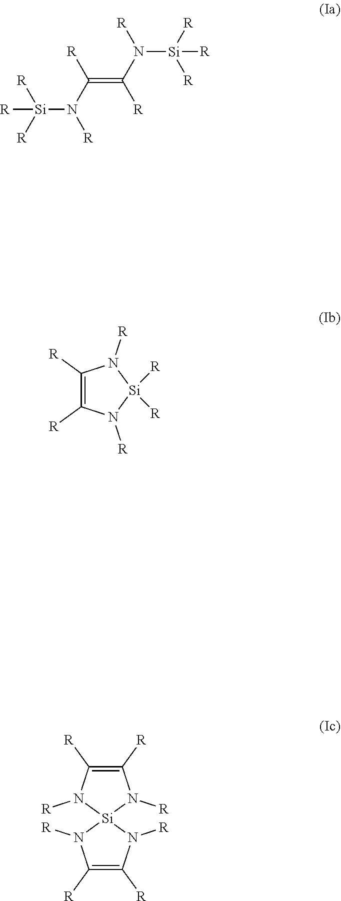
wherein R is hydrogen or an alkyl group.

8. The process of claim 1, wherein the group which is capable of coordinating to the metal or semimetal atom comprises oxygen which is bonded to a silicon atom of the leaving group.

9. The process of claim 1, wherein the organic compound is a compound of general formula (IIa) or (IIb): 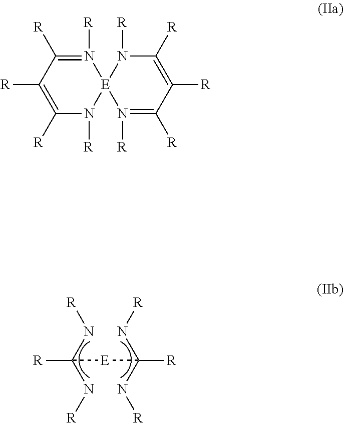
wherein R is hydrogen, an alkyl group, or a fluorinated alkyl group and
E is Si, Ge or Sn.

10. The process of claim 1, wherein the organic compound is a compound of general formula (IIIa) or (IIIb): 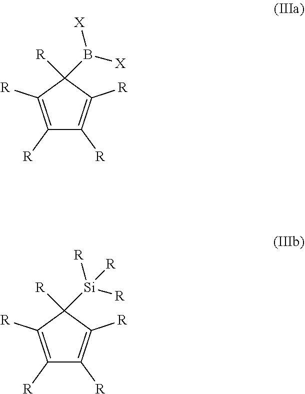
wherein R is hydrogen, an alkyl group, or a fluorinated alkyl group, and
X is a halogen.

11. The process of claim 1, wherein a sequence comprising activating a surface of the metal- or semimetal-comprising material, to obtain an activated surface, and then contacting the activated surface with an organic compound comprising a leaving group and a coordinating group is performed at least twice.

12. The process of claim 1, wherein the organic compound is in a vapor phase during the contacting.

13. The process of claim 1, comprising contacting the metal- or semimetal-comprising material having the activated surface with an organic solvent prior to the contacting with the organic compound.

14. (canceled)
